(19) United States
(12) Patent Application Publication
(10) Pub. No.: US 2020/0015384 A1
(43) Pub. Date: Jan. 9, 2020

(54) METHOD FOR MANUFACTURING A FLUID-BASED COOLING ELEMENT AND FLUID-BASED COOLING ELEMENT

(71) Applicant: EKWB d.o.o., Komenda (SI)

(72) Inventor: Niko Tivadar, Gornja Radgona (SI)

(73) Assignee: EKWB d.o.o.o, Komenda (SI)

(21) Appl. No.: 16/494,954

(22) PCT Filed: Mar. 23, 2018
(86) PCT No.: PCT/EP2018/057483

§ 371 Date: Sep. 17, 2019

(30) Foreign Application Priority Data
Mar. 24, 2017 (EP) 17162828.2

(51) Int. Cl. H05K 7/20; H05K 1/02

(52) U.S. Cl. CPC H05K 7/20254; H05K 2201/064; H05K 1/0203

(57) ABSTRACT

A method for manufacturing a fluid-based cooling element is provided. The fluid-based cooling element is configured for cooling a heat generating element arranged on a printed circuit board (100). The method comprises forming a base body comprising a plate-shaped base body portion and an inner base body portion integrally formed with the plate-shaped base body portion. The step of forming the base body comprises forming the plate-shaped base body portion and the inner base body portion by means of die casting. The inner base body portion comprises a plurality of protrusions formed on an upper side of the inner base body portion. The protrusions have a gap size in a range of 0.5 mm to 1.5 mm.

### CROSS-REFERENCE TO RELATED APPLICATIONS

This application is a National Phase application of International Application No. PCT/EP2018/057483, filed Mar. 23, 2018, which claims the benefit of EP Application 17162828.2, filed on Mar. 24, 2017, both of which are incorporated herein in their entireties.

### TECHNICAL FIELD

The invention relates to a method for manufacturing a fluid-based cooling element, wherein the fluid-based cooling element is configured for cooling a heat generating element arranged on a printed circuit board (PCB). Further, the invention relates to a fluid-based cooling element for cooling a heat generating element arranged on a printed circuit board.

### BACKGROUND

Normally, high performance cold plates (i.e. liquid or water blocks) for fluid-based cooling systems are made from a metal base (typically consisting of copper or aluminum) with a high-density heat sink fin structure above the high-heat flux area of the PCB component (typically a high-power microprocessor), a sealing lid with gaskets and inlet and outlet fluid connectors or ports.

Traditionally, the fluid-based cold plates, i.e. liquid or water blocks, are made from one or more raw bars of metal with a high thermal conductivity, in particular by removing (cutting) of the material to final shape. Here, one or more material removing techniques, such as machining, skiving, electro-erosion or other techniques are used. In low-volume production, the known cold plates are almost exclusively made by material cutting since this technique does not require any additional expensive tooling.

In high-volume production, raw metal bars are normally replaced by a die-casted, stamped, forged or extruded metal profile in order to ramp up the production rate. Such a preforming to shape reduces the machining time of the known cold plates as normally only a few structural details need to be produced of which the most important and time-consuming is the manufacturing of the heat sink cooling channels.

The heat sink cooling channels of the heat sink fin structure are most commonly made using a small diameter high-speed cutter, a wheel-type slit-saw, electro-erosion or a fin skiving technique. In this way, a linear array of heat sink fins is produced. Normally, the heat sink fin gap size can be made as thin as 0.1 mm in width for skived fins and 0.2 mm in width for slit-saw machined fins, depending on the cold plate material and technology.

In general, the higher the density of the heat sink fin structure or heat sink fin array is, the more efficient is the usage of the cooling surface of the cold plate in the area of the heat sink fin structure or heat sink fin array. Most commonly, a 0.2 mm to 0.8 mm thick heat sink fin structure is used for high-performance cold plates. Alternatively, the heat sink fin structure or heat sink fin array can also be soldered or welded to the base of the cold plate.

Thus, a high-density heat sink fin structure is crucial for achieving a good thermal performance of the cold plate, especially with heat generating PCB components reaching a relatively high heat flux up to 80 W/cm2.

FIG. 5 shows a base 12′ of a cold plate with such a high-density heat sink fin structure according to the prior art. The base 12′ of the cold plate shown in FIG. 5 is manufactured by using a known pre-forming technique. Then, the heat sink cooling channels of the heat sink fin structure are manufactured by using a small diameter high-speed cutter, a wheel-type slit-saw, electro-erosion or a fin skiving technique.

However, the use of such a technique drastically increases the production time as it requires additional machining as well as tooling/fixture costs and increases the production costs. In particular, any of the just-mentioned processing steps can amount up to half of the cold plate production costs.

Thus, a general problem of known methods for manufacturing high performance cold plates is that the same are not capable of the production of a high-density heat sink fin structure for achieving a good thermal performance while at the same time avoiding a relatively time-consuming, complicated and costly processing step.

### BRIEF DESCRIPTION

It is an object of the invention to specify a method for manufacturing a fluid-based cooling element which allows for the production of the same in an efficient, simple and economical way while achieving a good thermal performance.

This object is solved by a method having the features of claim 1 and by a fluid-based cooling element having the features of claim 15. Advantageous developments of the invention are specified in the dependent claims.

According to an embodiment, a method for manufacturing a fluid-based cooling element is provided. The fluid-based cooling element is configured for cooling a heat generating element arranged on a printed circuit board. The method comprises forming a base body comprising a plate-shaped based body portion and an inner base body portion integrally formed with the plate-shaped base body portion. The step of forming the base body comprises forming the plate-shaped base body portion and the inner base body portion by means of die casting. The inner base body portion comprises a plurality of protrusions formed on an upper side of the inner base body portion. The protrusions have a gap size in a range of 0.5 mm to 1.5 mm. Preferably, the step of forming the base body comprises forming the plate-shaped base body portion and the inner base body portion in a single processing step. In this way, the production of a fluid-based cooling element can be achieved in an efficient, simple and economical way. Simultaneously, the fluid-based cooling element is characterized by a good thermal performance.

Preferably, the protrusions have a gap size of approximately 1 mm. Thus, on the one hand, a sufficiently high density of a heat sink fin arrangement can be provided, and on the other hand, the heat sink fin arrangement can be made relatively robust.

It is advantageous when the step of forming the base body comprises using an aluminum-silicon die casting alloy, wherein the aluminum-silicon die casting alloy is G-AlSi12. This die casting alloy G-AlSi12 offers excellent die casting properties while maintaining a high thermal conductivity, casting yield rate and corrosion resistance.

Preferably, the aluminum-silicon die casting alloy G-AlSi12 is substantially free of copper. Thus, it is possible to effectively avoid galvanic corrosion which increases the reliability of the fluid-based cooling element.

Alternatively, the step of forming the base body comprises using an aluminum-silicon-magnesium die casting alloy or using an aluminum-magnesium die casting alloy. For example, the aluminum-silicon-magnesium die casting alloy is G-AlSi7Mg, G-AlSi5Mg, G-AlMg5Si or G-AlSi10Mg. Further, the aluminum-magnesium die casting alloy may be G-AlMg3 or G-AlMg5. Thus, several different aluminum-based die casting alloys can be used for the production of the fluid-based cooling element.

It is advantageous when the protrusions extend parallel to an upper surface of the plate-shaped base body portion, when the protrusions define a plurality of fluid channels extending parallel to the upper surface of the plate-shaped base body portion, and when the protrusions are configured as a heat sink fin arrangement. This allows to effectively cool a high-heat flux area arranged below the heat sink fin arrangement.

It is advantageous when a first individual protrusion of the plurality of protrusions extends into a first longitudinal direction parallel to an upper surface of the plate-shaped base body portion, when a second individual protrusion of the plurality of protrusions extends into a second longitudinal direction parallel to the upper surface of the plate-shaped base body portion, when the extension of the first individual protrusion in the first longitudinal direction defines a first angle with respect to a symmetry axis of the plurality of protrusions extending parallel to the upper surface of the plate-shaped base body portion, when the extension of the second individual protrusion in the second longitudinal direction defines a second angle with respect to the symmetry axis of the plurality of protrusions extending parallel to the upper surface of the plate-shaped base body portion, and when the first angle and/or the second angle are equal to or larger than 15° and smaller than 90°. Thereby, a non-linear array of heat sink fins can be provided which increases the length of the fluid channels or heat sink cooling channels and in turn the effective heat sink surface. In addition, the hydraulic performance can also be improved.

Preferably, the first angle and the second angle are of the same size. Thus, a symmetric configuration of the heat sink fin arrangement can be obtained.

It is advantageous when the method further comprises forming a nozzle body comprising a longitudinally extending fluid inlet, wherein the step of forming the nozzle body comprises using an aluminum-based die casting alloy. This allows to provide a central inlet split-flow nozzle which can be used to generate a split fluid flow for the heat sink fin arrangement. Thereby, the thermal performance can be improved while at the same time a hydraulic restriction of the fluid-based cooling element can be decreased.

Preferably, the method further comprises arranging the nozzle body on the inner base body portion, wherein the longitudinally extending fluid inlet is arranged perpendicular above a symmetry axis of the plurality of protrusions formed on the upper side of the inner base body portion. Thereby, the generation of the split fluid flow for the heat sink fin arrangement can be optimized.

Preferably, the method further comprises arranging a sealing element on/or in the plate-shaped base body portion. Thereby, a leakage of the cooling fluid from the fluid chamber can effectively be prevented.

It is advantageous when the method further comprises arranging a sealing body on the plate-shaped base body portion, wherein the plate-shaped base body portion, the inner base body portion and the sealing body together define a fluid chamber, and when the fluid chamber is configured for receiving a cooling fluid. This allows to obtain a controlled and reliable flow of the cooling fluid within the fluid chamber.

According to an embodiment, a fluid-based cooling element for cooling a heat generating element arranged on the printed circuit board comprises a base body comprising a plate-shaped base body portion and an inner base body portion integrally formed with the plate-shaped base body position. The plate-shaped base boy portion and the inner base body portion are formed by means of die casting. The inner base body portion comprises a plurality of protrusions formed on an upper side of the inner base body portion. The protrusions have a gap size in a range of 0.5 mm to 1.5 mm.

For example, the heat generating element may be a microprocessor, integrated circuit, or any other PCB component arranged on the printed circuit board, e.g. a memory IC (RAM), a non-volatile storage IC (flash storage), a bus line switch (PCle switch), an FPGA, an ASIC, an I/O-controller, a PHY controller, a coil, a diode and a voltage converter.

### BRIEF DESCRIPTION OF THE DRAWINGS

Further features and advantages of the invention result from the following description which explains the invention in more detail on the basis of embodiments in connection with the enclosed schematic figures:

FIG. 1 shows a top perspective view of a base body of an embodiment of a fluid-based cooling element;

FIG. 2 shows a top view of the base body according to FIG. 1 illustrating a heat sink fin arrangement;

FIG. 3 shows a top view of an exemplary nozzle body arranged on the heat sink fin arrangement of the base body according to FIG. 1;

FIG. 4 shows an exploded view of the embodiment of the fluid-based cooling element fixable to a printed circuit board; and

FIG. 5 shows a top perspective view of a base body of a fluid-based cooling element according to the prior art.

### DETAILED DESCRIPTION

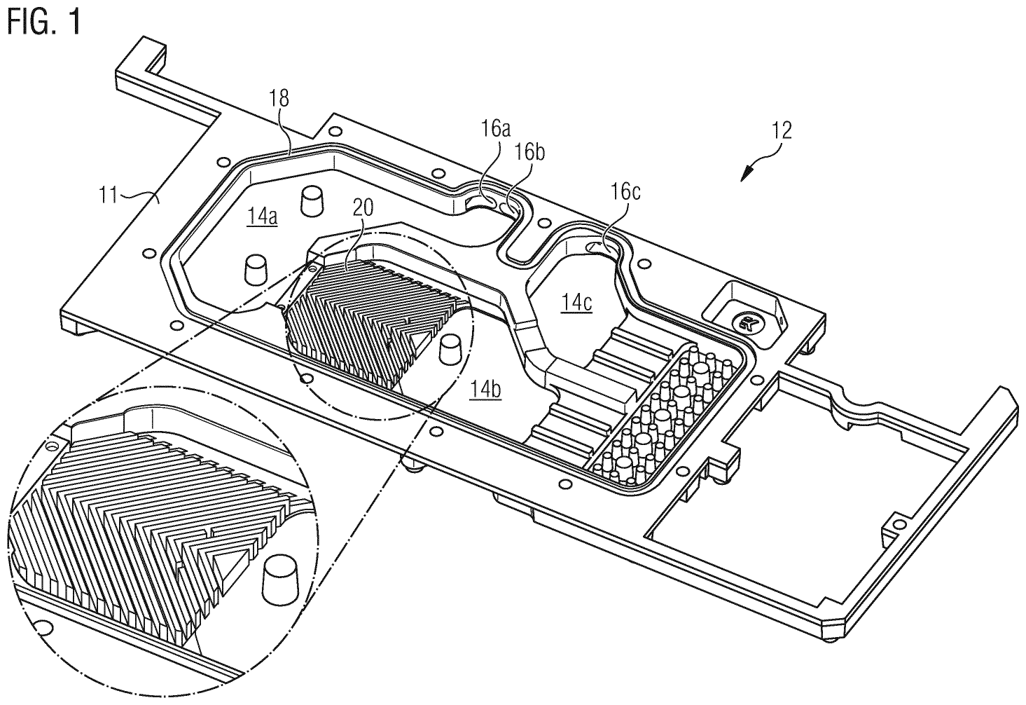

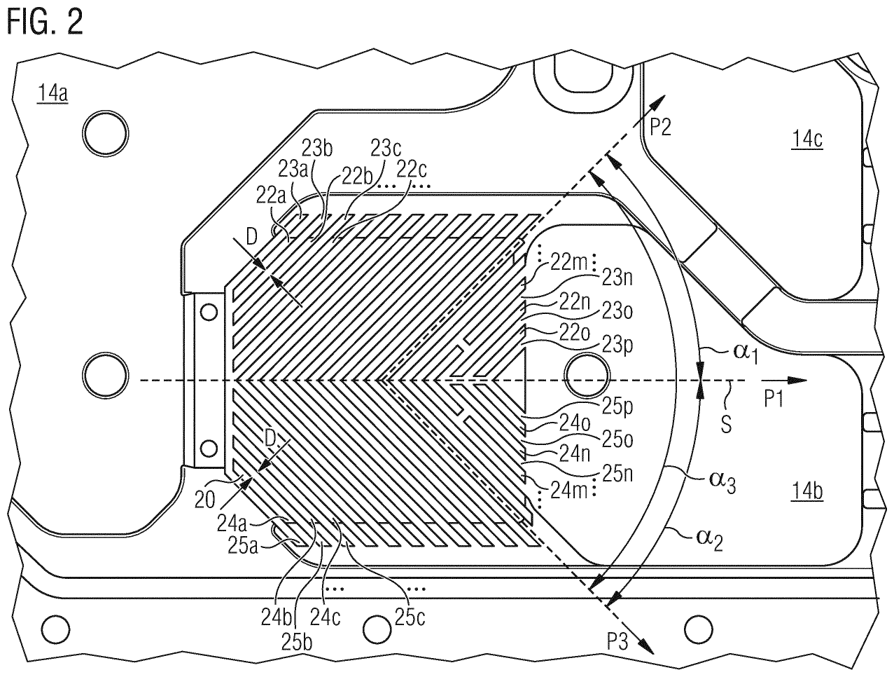

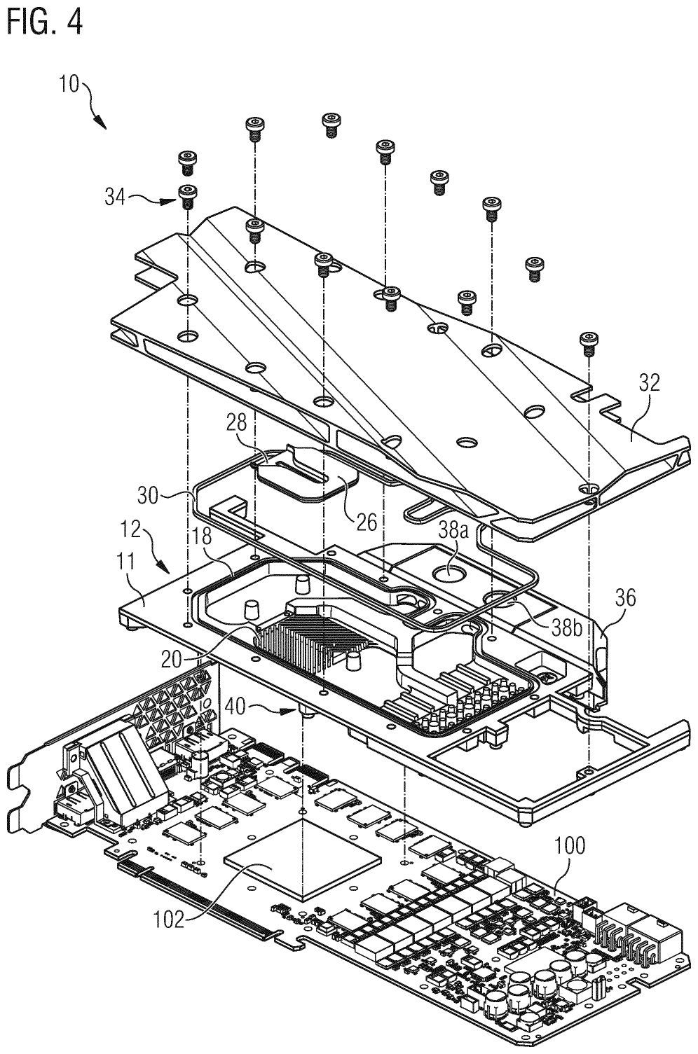

FIG. 1 shows a top perspective view of a base body 12 of an embodiment of a fluid-based cooling element 10 (cf. FIG. 4). As shown in FIG. 1, the base body 12 comprises a plate-shaped base body portion 11 and an inner base body portion 20 integrally formed with the plate-shaped base body portion 11. The plate-shaped base body portion 11 comprises a plurality of inner recess portions 14a to 14c configured to define a fluid chamber for receiving a cooling fluid. The plate-shaped base body portion 11 further comprises a plurality of fluid openings 16a to 16c and a circumferential recess portion 18 surrounding the inner recess portions 14a to 14c. The fluid openings 16a to 16c are implemented to provide a fluidic connection between the fluid chamber defined by the inner recess portions 14a to 14c and a fluid inlet and a fluid outlet. The circumferential recess portion 18 is formed in an upper surface of the plate-shaped base body portion 11 and is configured for receiving a sealing element, such as a sealing gasket. As further shown in FIG. 1, the inner base body portion 20 comprises a heat sink fin arrangement extending into the fluid chamber defined within the plate-shaped base body portion 11. More details of the heat sink fin arrangement are subsequently described with reference to FIG. 2.

In particular, the base body 12 shown in FIG. 1 is obtained by means of pressure die casting of the aluminum-silicon die casting alloy G-AlSi12.

FIG. 2 shows a top view of the base body 12 according to FIG. 1 illustrating the heat sink fin arrangement. In particular, the inner base body portion 20 comprises a plurality of protrusions 22a to 22o and 24a to 24o formed on an upper side of the inner base body portion 20. The protrusions 22a to 22o and 24a to 24o extend parallel to an upper surface of the plate-shaped base body portion 11 and define a plurality of fluid channels 23a to 23p and 25a to 25p extending parallel to the upper surface of the plate-shaped base body portion 11.

As shown in FIG. 2, the heat sink fin arrangement comprises a first group of protrusions 22a to 22o and a second group of protrusions 24a to 24o arranged symmetrically with respect to a symmetry axis S of the plurality of protrusions 22a to 22o and 24a to 24o. The heat sink fin arrangement shown in FIG. 2 can also be referred to as a non-linear array of heat sink fins. Here, the heat sink fins are formed by the plurality of protrusions 22a to 22o and 24a to 24o.

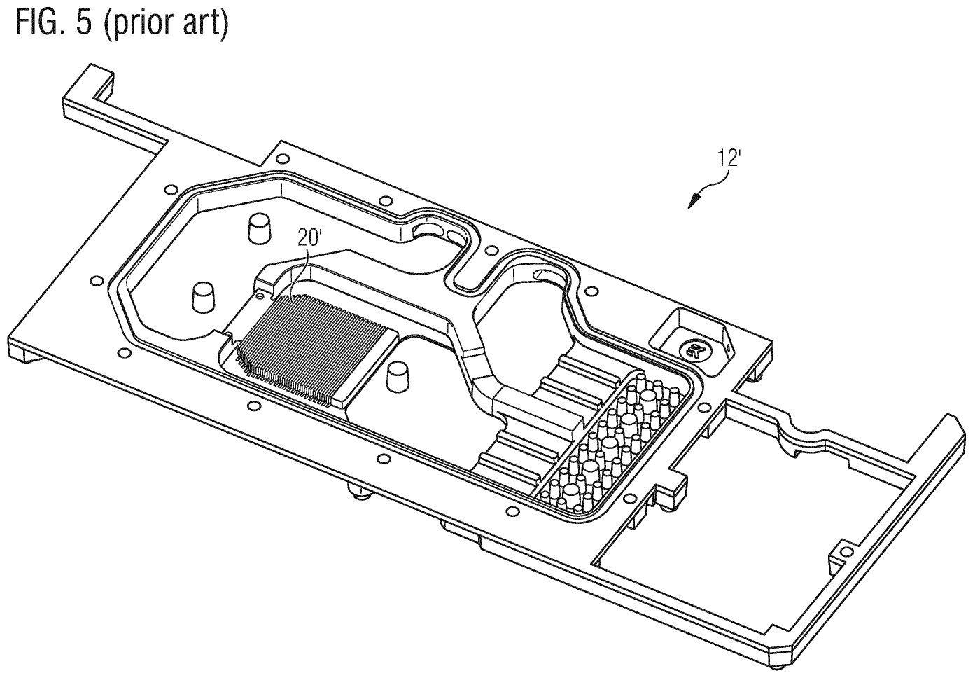

Referring to FIG. 2, a first individual protrusion (i.e. any of the protrusions 22a to 22o of the first group) extends into a first longitudinal direction parallel to an upper surface of the plate-shaped base body portion 11 and a second individual protrusion (i.e. any of the protrusions 24a to 24o of the second group) extends into a second longitudinal direction parallel to the upper surface of the plate-shaped base body portion 11. In FIG. 2, the direction of the input fluid flow is indicated by the arrow P1, while the first longitudinal direction and the second longitudinal direction are indicated by the arrows P2 and P3, respectively. Further referring to FIG. 2, the extension of the first individual protrusion in the first longitudinal direction defines a first angle α1 with respect to the symmetry axis S and the extension of the second individual protrusion in the second longitudinal direction defines a second angle α2 with respect to the symmetry axis S. In the heat sink fin arrangement of FIG. 2, the first angle α1 and/or the second angle α2 are equal to or larger than 15° and smaller than 90°. Thus, the non-linear array of heat sink fins shown in FIG. 2 is substantially different from the known linear or straight heat sink fin structure 20′ shown in FIG. 5.

For obtaining an optimal fluid flow (which is symmetrical to the symmetry axis S), the first angle α1 and the second angle α2 are of the same size. Here, the total angle α3 defined by the first longitudinal direction and the second longitudinal direction is equal to or larger than 30° and smaller than 180° . The provision of the heat sink fin arrangement of FIG. 2 allows to increase the length of the fluid channels 23a to 23p and 25a to 25p, and thus the thermal performance of the fluid-based cooling element 10 can be improved.

As shown in FIG. 2, the protrusions 22a to 22o of the first group and the protrusions 24a to 24o of the second group extend parallel to each other, respectively. Here, the protrusions 22a to 22o of the first group and the protrusions 24a to 24o of the second group have a same gap size D. The gap size D may be defined as an average of the minimum distance between two adjacent protrusions (i.e. protrusions 22a, 22b; 22b, 22c; . . . 22n, 22o) of the first group or between two adjacent protrusions (i.e. protrusions 24a, 24b; 24b, 24c; . . . 24n, 24o) of the second group. In particular, the protrusions 22a to 22o and 24a to 24o have a gap size D in a range of 0.5 mm to 1.5 mm. For example, the gap size D is in a range of 0.6 mm to 1.4 mm, 0.7 mm to 1.3 mm, 0.8 mm to 1.2 mm or 0.9 mm to 1.1 mm. Preferably, the gap size D is 1 mm ±0.1 mm.

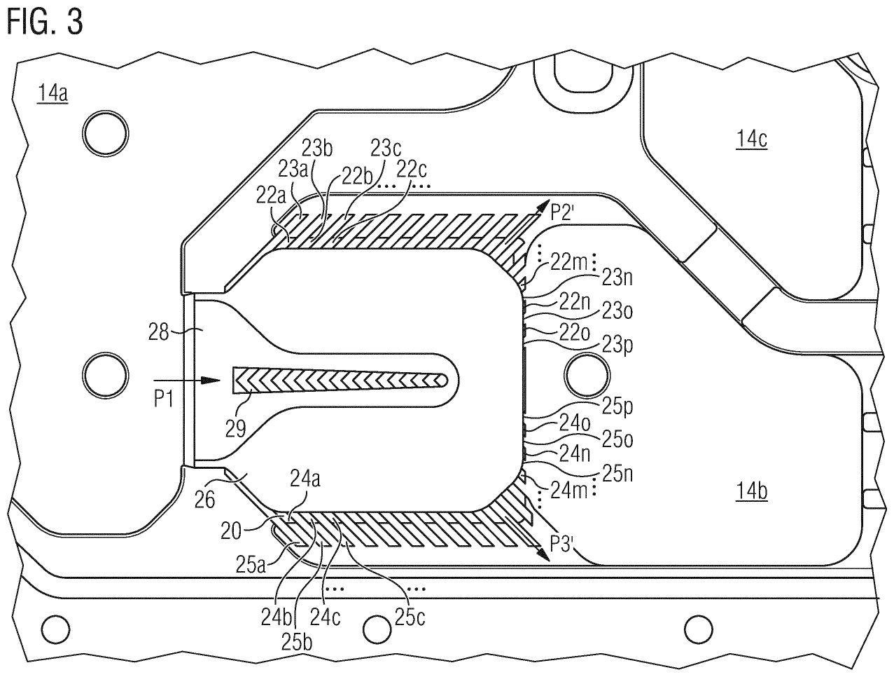

FIG. 3 shows a top view of an exemplary nozzle body 26 arranged on the heat sink fin arrangement of the base body 12 according to FIG. 1. The nozzle body 26 is obtained by means of die casting using an aluminum-based die casting alloy. As shown in FIG. 3, the nozzle body 26 comprises an inner recess portion 28 tapering in the direction of the input fluid flow P1. As further shown in FIG. 3, the nozzle body 26 comprises a longitudinally extending fluid inlet 29 configured to split the input fluid flow in the direction P1 into a first output fluid flow in the direction P2′ and a second output fluid flow in the direction P3′. Here, the direction P2′ and the direction P3′ are parallel to the first longitudinal direction P2 and the second longitudinal direction P3 shown in FIG. 2. Referring to FIG. 3, the nozzle body 26 is arranged on the inner base body portion 20 such that the longitudinally extending fluid inlet 29 is aligned with the symmetry axis S of the plurality of protrusions 22a to 22o and 24a to 24o. By this arrangement of the nozzle body 26, it is possible to generate the split fluid flow in a controllable and reliable way.

FIG. 4 shows an exploded view of the embodiment of the fluid-based cooling element 10 fixable to a printed circuit board 100. The printed circuit board 100 comprises a heat generating element 102 to be cooled (e.g. a high-power microprocessor). The fluid-based cooling element 10 is configured to be fixed to the printed circuit board 100 by means of fixing members 40. In particular, the fluid-based cooling element 10 is fixable to the printed circuit board 100 such that the inner base body portion 20 is arranged above the heat generating element 102. By providing a mechanical and thermal contact, the heat generating element 102 can efficiently be cooled by the fluid-based cooling element 10.

As shown in FIG. 4, the fluid-based cooling element 10 comprises the base body 12 comprising the plate-shaped base body portion 11 and the inner base body portion 20 integrally formed with the plate-shaped base body portion 11. As further shown in FIG. 4, the fluid-based cooling element 10 comprises a sealing element 30 configured to be received by the circumferential recess portion 18 formed in the upper surface of the plate-shaped base body portion 11. The fluid-based cooling element 10 further comprises the nozzle body 26 with the inner recess portion 28 configured to be arranged perpendicular above the inner base body portion 20 so as to be in mechanical and thermal contact with the heat sink fins formed on the upper side of the inner base body portion 20.

The fluid-based cooling element 10 further comprises a sealing body 32 configured to be arranged on the plate-shaped base body portion 11. The sealing body 32 is plate-shaped and can be fixed to the plate-shaped base body portion 11 by means of a plurality of fixing elements, such as screws 34. In the assembled state, the plate-shaped base body portion 11, the inner base body portion 20 and the sealing body 32 together define the fluid chamber. With reference to FIG. 4, a connecting element 36 may be provided on one side of the base body 12 comprising a fluid inlet 38a and a fluid outlet 38b. By means of the fluid inlet 38a and the fluid outlet 38b, a controlled fluid flow though the fluid chamber defined within the plate-shaped base body portion 11 can be provided.

Embodiments of the invention provide a rapid production of high performance cold plates (i.e. the fluid-based cooling element 10) using a pressure die casting of the aluminum-based alloy G-AlSi12 where the complete cooling fin heat sink structure can be die casted in a single operation, without any further manufacturing process. Embodiments of the invention provide the advantage that the cooling fin gap size D can be as small as 1 mm or less. Contrary to the known pre-forming techniques, embodiments of the invention allow for the production of a high-density heat sink fin structure with filigrane heat sink cooling channels. Here, the use of the afore-mentioned alloy G-AlSi12 is preferred since it offers excellent die casting properties while maintaining a high thermal conductivity, casting yield rate and corrosion resistance.

The employed die casting alloy is substantially copper-free (<0.05%) which further improves the reliability of the cold plate 10 by avoiding galvanic corrosion. Depending on the application, the following alloys can be used as well: G-AlSi7Mg, G-AlSi5Mg, G-AlMg3, G-A1Mg5, G-A1Mg5Si or G-AlSil0Mg.

Here, it should be noted that since pure aluminum has a low strength and is difficult to cast, it is typically used only for special applications such as electric motor components for which a high electric and thermal conductivity is required. However, the use of silicon (Si) as an exemplary additive in the employed aluminum alloys is advantageous since it lowers the melting point and increases the melt flow, fluidity, hardness and strength.

Instead of a linear array of heat sink fins according to the prior art, embodiments of the invention provide a non-linear cooling fin array design where the angle αbetween both halfs of the heat sink fin structure is equal to or larger than 30° and smaller than 180° . This inventive design lengthens the cooling channels which in turn increases the effective heat sink surface (up to 40% compared to a straight fin array structure). Further, the hydraulic performance can be improved.

According to embodiments, a central fluid inlet split-flow design can be used in order to increase the thermal performance of the cold plate 10 while at the same time decreasing the hydraulic restriction. In particular, a central inlet split-flow nozzle 26 is provided which can also be made from a die casting aluminum-based alloy. This helps to improve the cooling performance of the cold plate 10 as the nozzle 26 and the cold plate fin structure are in a mechanical and thus thermal contact. Alternatively, the nozzle 26 can also be made from another material, like plastic, albeit without additional thermal performance gains.

In order to further increase the production rate, embodiments of the invention also allow for a welding of a sealing lid which eliminates the need for sealing gaskets and fasteners.

The invention also provides the advantage that due to the specific size or density of the cooling fin structure, there is substantially no danger of a heat induced deformation of the cooling fin array, especially when compared to a thinner structure made by using skiving or other material removal techniques.

1. A method for manufacturing a fluid-based cooling element, wherein the fluid-based cooling element is configured for cooling a heat generating element (102) arranged on a printed circuit board (PCB), wherein the method comprises:
forming a base body comprising a plate-shaped base body portion and an inner base body portion integrally formed with the plate-shaped base body portion,
wherein the step of forming the base body comprises forming the plate-shaped base body portion and the inner base body portion by means of die casting,
wherein the inner base body portion comprises a plurality of protrusions formed on an upper side of the inner base body portion, and
wherein the protrusions have a gap size in a range of 0.5 mm to 1.5 mm.

2. The method according to claim 1, wherein the protrusions have a gap size of approximately 1 mm.

3. The method according to claim 1, wherein the step of forming the base body comprises using an aluminum-silicon die casting alloy, wherein the aluminum-silicon die casting alloy is G-AlSi12.

4. The method according to claim 3, wherein the aluminum-silicon die casting alloy G-AlSi12 is substantially free of copper.

5. The method according to claim 1, wherein the step of forming the base body comprises using an aluminum-silicon-magnesium die casting alloy or using an aluminum-magnesium die casting alloy.

6. The method according to claim 5, wherein the aluminum-silicon-magnesium die casting alloy is G-AlSi7Mg, G-AlSi5Mg, G-AlMg5Si or G-AlSi10Mg, and wherein the aluminum-magnesium die casting alloy is G-AlMg3 or G-AlMg5.

7. The method according to claim 1, wherein the protrusions extend parallel to an upper surface of the plate-shaped base body portion, wherein the protrusions define a plurality of fluid channels extending parallel to the upper surface of the plate-shaped base body portion, and wherein the protrusions are configured as a heat sink fin arrangement.

8. The method according to claim 1, wherein a first individual protrusion of the plurality of protrusions extends into a first longitudinal direction parallel to an upper surface of the plate-shaped base body portion, wherein a second individual protrusion of the plurality of protrusions extends into a second longitudinal direction parallel to the upper surface of the plate-shaped base body portion it wherein the extension of the first individual protrusion in the first longitudinal direction defines a first angle (α₁) with respect to a symmetry axis of the plurality of protrusions extending parallel to the upper surface of the plate-shaped base body portion, wherein the extension of the second individual protrusion in the second longitudinal direction defines a second angle (α₂) with respect to the symmetry axis of the plurality of protrusions extending parallel to the upper surface of the plate-shaped base body portion, and wherein the first angle (α₁) and/or the second angle (α₂) are equal to or larger than 15° and smaller than 90°.

9. The method according to claim 8, wherein the first angle (α₁) and the second angle (α₂) are of the same size.

10. The method according to claim 1, wherein the method further comprises forming a nozzle body comprising a longitudinally extending fluid inlet, wherein the step of forming the nozzle body comprises using an aluminum-based die casting alloy.

11. The method according to claim 10, wherein the method further comprises arranging the nozzle body on the inner base body portion, wherein the longitudinally extending fluid inlet is arranged perpendicular above a symmetry axis of the plurality of protrusions formed on the upper side of the inner base body portion.

12. The method according to claim 1, wherein the method further comprises arranging a sealing element on or in the plate-shaped base body portion.

13. The method according to claim 1, wherein the method further comprises arranging a sealing body on the plate-shaped base body portion, wherein the plate-shaped base body portion, the inner base body portion and the sealing body together define a fluid chamber, wherein the fluid chamber is configured for receiving a cooling fluid.

14. The method according to claim 1, wherein the step of forming the base body comprises forming the plate-shaped base body portion and the inner base body portion in a single processing step.

15. A fluid-based cooling element for cooling a heat generating element arranged on a printed circuit board, wherein the fluid-based cooling element comprises:
a base body comprising a plate-shaped base body portion and an inner base body portion integrally formed with the plate-shaped base body portion, wherein the plate-shaped base body portion and the inner base body portion are formed by means of die casting,
wherein the inner base body portion comprises a plurality of protrusions formed on an upper side of the inner base body portion, and
wherein the protrusions have a gap size in a range of 0.5 mm to 1.5 mm.
